(19) United States
(12) Patent Application Publication
(10) Pub. No.: US 2023/0411412 A1
(43) Pub. Date: Dec. 21, 2023

(54) SEMICONDUCTOR STRUCTURE AND FORMING METHOD THEREOF

(71) Applicant: CHANGXIN MEMORY TECHNOLOGIES, INC., Hefei City (CN)

(72) Inventors: Deyuan XIAO, Hefei City (CN); Kanyu Cao, Hefei City (CN)

(21) Appl. No.: 17/933,940

(22) Filed: Sep. 21, 2022

Related U.S. Application Data
(63) Continuation of application No. PCT/CN2022/102860, filed on Jun. 30, 2022.

(30) Foreign Application Priority Data
Jun. 21, 2022 (CN) 202210706322.2

(51) Int. Cl. H01L 27/13; H01L 27/12; H01L 21/84

(52) U.S. Cl. CPC H01L 27/13; H01L 27/1203; H01L 21/84

(57) ABSTRACT

The present disclosure relates to a semiconductor structure and a forming method thereof. The semiconductor structure includes: a substrate; a capacitive structure, located on a top surface of the substrate and including a plurality of capacitors arranged in an array along a first direction and a second direction, wherein the first direction and the second direction are each parallel to the top surface of the substrate, and the first direction intersects with the second direction; a transistor structure, located above the capacitive structure and including a plurality of active pillars and a plurality of word lines, wherein the active pillar is electrically connected to the capacitor, and the word line extends along the second direction and continuously cover the active pillars arranged at intervals along the second direction; and a bit line structure, located above the transistor structure and including a plurality of bit lines.

### CROSS-REFERENCE TO RELATED APPLICATIONS

This is a continuation of International Application No. PCT/CN2022/102860, filed on Jun. 30, 2022, which claims the priority of Chinese Patent Application No. 202210706322.2, filed on Jun. 21, 2022 and entitled “SEMICONDUCTOR STRUCTURE AND FORMING METHOD THEREOF”. The entire contents of International Application No. PCT/CN2022/102860 and Chinese Patent Application No. 202210706322.2 are incorporated herein by reference.

### TECHNICAL FIELD

The present disclosure relates to the technical field of semiconductor manufacturing, and in particular to a semiconductor structure and a forming method thereof.

### BACKGROUND

As a semiconductor device commonly used in an electronic device such as a computer, a dynamic random access memory (DRAM) includes a plurality of memory cells, and each of the memory cells usually includes a transistor and a capacitor. The transistor has a gate being electrically connected to a word line, a source being electrically connected to a bit line, and a drain being electrically connected to the capacitor. A word line voltage on the word line can control on and off of the transistor, such that data information stored in the capacitor can be read through the bit line or data information can be written into the capacitor through the bit line.

The semiconductor structure such as a DRAM with a transistor on capacitor (TOC) structure is not compatible with peripheral circuits due to the structural limitation, and leakage easily occurs between a capacitor and a substrate. In addition, the manufacturing process of DRAM and other semiconductor structure is complex and has high manufacturing cost.

Therefore, how to improve the performance of the semiconductor structure and reduce the difficulty of the semiconductor manufacturing process is an urgent technical problem to be solved.

### SUMMARY

A semiconductor structure and a forming method thereof provided by some embodiments of the present disclosure.

According to some embodiments, the present disclosure provides a semiconductor structure, including:
a substrate;
a capacitive structure, located on a top surface of the substrate and including a plurality of capacitors arranged in an array along a first direction and a second direction, where the first direction and the second direction are each parallel to the top surface of the substrate, and the first direction intersects with the second direction;
a transistor structure, located above the capacitive structure and including a plurality of active pillars and a plurality of word lines, wherein the active pillar is electrically connected to the capacitor, and the word line extends along the second direction and continuously cover the active pillars arranged at intervals along the second direction; and a bit line structure, located above the transistor structure and including a plurality of bit lines, wherein the bit line extends along the first direction and are electrically connected to the active pillars arranged at intervals along the first direction.

According to other embodiments, the present disclosure provides a method of forming a semiconductor structure, including:
providing an initial substrate;
forming, in the initial substrate, a substrate and a capacitive structure located on a top surface of the substrate, where the capacitive structure includes a plurality of capacitors arranged in an array along a first direction and a second direction, the first direction and the second direction are each parallel to the top surface of the substrate, and the first direction intersects with the second direction;
forming, in the initial substrate, a transistor structure located above the capacitive structure, wherein the transistor structure includes a plurality of active pillars and a plurality of word lines, the active pillar is electrically connected to the capacitor, and the word line extends along the second direction and continuously cover the active pillars arranged at intervals along the second direction; and
forming a bit line structure above the transistor structure, where the bit line structure includes a plurality of bit lines, and the bit line extends along the first direction and are electrically connected to the active pillars arranged at intervals along the first direction.

### BRIEF DESCRIPTION OF THE DRAWINGS

FIG. 1 is a schematic diagram of a semiconductor structure according to a specific implementation of the present disclosure;

FIG. 2 is a flowchart of a method of forming a semiconductor structure according to a specific implementation of the present disclosure; and

FIG. 3 to FIG. 15 are schematic structural diagrams of main processes for forming a semiconductor structure according to a specific implementation of the present disclosure.

### DETAILED DESCRIPTION

Specific implementations of a semiconductor structure and a forming method thereof provided in the present disclosure are described in detail below with reference to the accompanying drawings.

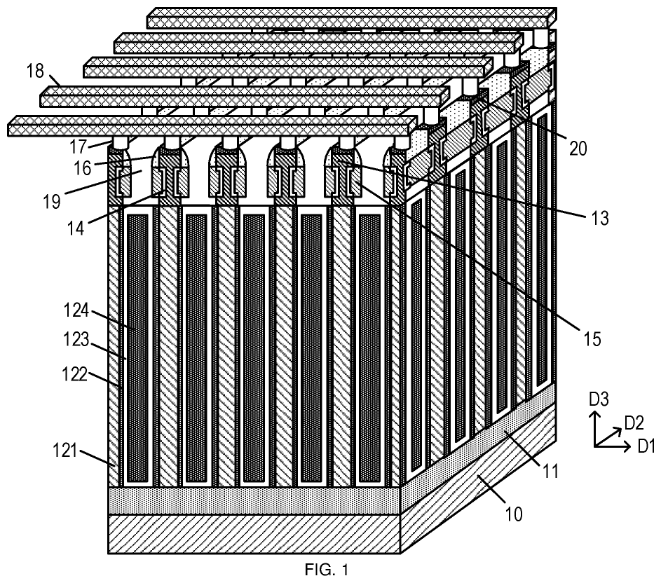

The specific implementation provides a semiconductor structure. FIG. 1 is a schematic structural diagram of a semiconductor structure according to a specific implementation of the present disclosure. In the specific implementation, the semiconductor structure may be, but is not limited to, a DRAM. As shown in FIG. 1, the semiconductor structure in the specific implementation includes:
a substrate 10;
a capacitive structure, located on a top surface of the substrate 10 and including a plurality of capacitors arranged in an array along a first direction D1 and a second direction D2, where the first direction D1 and the second direction D2 are each parallel to the top surface of the substrate 10, and the first direction D1 intersects with the second direction D2;
a transistor structure, located above the capacitive structure and including a plurality of active pillars 13 and a plurality of word lines 15, where the active pillar 13 is electrically connected to the capacitor, and the word line 15 extends along the second direction D2 and continuously cover the active pillars 13 arranged at intervals along the second direction D2; and
a bit line structure, located above the transistor structure and including a plurality of bit lines 18, where the bit line 18 extends along the first direction D1 and are electrically connected to the active pillars 13 arranged at intervals along the first direction D1.

Specifically, the substrate 10 may be, but is not limited to, a silicon substrate. This specific implementation is described by taking the substrate being the silicon substrate as an example. In other examples, the substrate 10 may be a semiconductor substrate such as a gallium nitride substrate, a gallium arsenide substrate, a gallium carbide substrate, a silicon carbide substrate, or a silicon-on-insulator (SOI) substrate. The substrate 10 is configured to support device structures thereon. A top surface of the substrate 10 refers to a surface of the substrate 10 on which the capacitive structure is formed.

The capacitive structure includes the plurality of capacitors arranged in a two-dimensional array along the first direction D1 and the second direction D2. Each of the capacitors extends along a third direction D3, where the third direction D3 is a direction perpendicular to the top surface of the substrate 10. The transistor structure is located above the capacitive structure, and the transistor structure includes the plurality of active pillars 13 arranged in a two-dimensional array along the first direction D1 and the second direction D2. The active pillar 13 includes a channel region, and a drain region and a source region arranged on two opposite sides of the channel region along the third direction D3. The capacitor is in contact with and electrically connected to the drain region. The transistor structure further includes a plurality of word lines 15, and a word line isolation layer 19 located between adjacent ones of the word lines 15. The word line 15 extends along the second direction D2, and continuously cover the active pillars 13 arranged at intervals along the second direction D2, to form the word line 15 of a channel-all-around structure. The bit line structure includes the plurality of bit lines 18. The bit line 18 is located above the transistor structure, such that the bit line 18 can be formed by using a metal material such as tungsten, thereby reducing the resistance of the bit lines and manufacturing difficulty of the bit lines. Moreover, by arranging the bit line 18 above the transistor structure, the bit line is compatible with peripheral circuit processes such as a processor core (CORE), a sense amplifier (SA), and input/output (I/O).

In some embodiments, the capacitor includes:
a bottom electrode, including a conductive pillar 121 and a conductive layer 122 covering a surface of the conductive pillar 121, where a top surface of the conductive pillar 121 is in contact with and electrically connected to the active pillar 13;
a dielectric layer 123, covering a surface of the conductive layer 122; and
a top electrode 124, covering a surface of the dielectric layer 123.

Specifically, the bottom electrode in the capacitor includes the conductive pillar 121 extending along the third direction D3 and the conductive layer 122 covering a sidewall is of the conductive pillar 121. The dielectric layer 123 covers a sidewall of the conductive layer 122, a surface of the substrate isolation layer 11, and a bottom surface of the word line isolation layer 19. The top electrode 124 covers the surface of the dielectric layer 123.

In some embodiments, the dielectric layer 123 is made of any one or more of strontium titanate, aluminum oxide, zirconium oxide, and hafnium oxide, and the conductive layer 122 and the top electrode 124 each are made of any one or more of titanium, ruthenium, ruthenium oxide, and titanium nitride.

Specifically, the dielectric layer 123 may be made of a strontium titanate (STO) material with a high dielectric constant (HK); the conductive layer 122 and the top electrode 124 may be made of ruthenium or ruthenium oxide, etc., thereby reducing the height of the capacitor along the third direction D3, and reducing the etching depth during etching if the capacitor hole for forming the capacitor, to further reduce the process difficulty. In other examples, the dielectric layer 123 may be made of any one or more of aluminum oxide, zirconium oxide, and hafnium oxide; accordingly, the conductive layer 122 and the top electrode 124 are made of TiN, etc., to reduce the manufacturing cost of the semiconductor layer structure.

In some embodiments, a material of the conductive pillar 121 is a silicide material including first dopant ions, to enhance the conductivity of the conductive pillar 121. In an embodiment, the drain region includes second dopant ions. The second dopant ions and the first dopant ions are of a same type, to further reduce the contact resistance between the conductive pillar 121 and the drain region.

In some embodiments, the semiconductor structure further includes:
a substrate isolation layer 11, located between the substrate 10 and the capacitive structure.

Specifically, a material of the substrate isolation layer 11 may be, but is not limited to, an insulation material such as an oxide (such as silicon dioxide). The substrate isolation layer 11 is formed between the substrate 10 and the capacitive structure to isolate an electrical leakage channel from the bottom of the capacitor to the substrate 10, thereby reducing the electrical leakage between the capacitor and the substrate 10.

In some embodiments, the substrate isolation layer 11 includes:
a first substrate isolation sub-layer, continuously distributed below the plurality of conductive pillars 121; and
a second substrate isolation sub-layer, covering a surface of the first substrate isolation sub-layer.

Specifically, the substrate isolation layer 11 includes the first substrate isolation sub-layer continuously distributed below the plurality of conductive pillars 121 and the second substrate isolation sub-layer covering the surface of the first substrate isolation sub-layer, such that the forming process of the substrate isolation layer can be carried out while the capacitor hole is formed, to ensure that the substrate isolation layer is directly formed below the capacitor, thereby ensuring that the substrate isolation layer can be fully aligned with the bottom of the capacitor. This simplifies a manufacturing process of the semiconductor structure and reduces process difficulty of the semiconductor structure, and can further improve an effect of electrical isolation between the capacitor and the substrate.

In other examples, the substrate isolation layer 11 may also be a single-layer structure. For example, the substrate isolation layer 11 is a single oxide layer located between the substrate 10 and the capacitive structure.

In some embodiments, each of the active pillars 13 includes a channel region, and a drain region and a source region that are arranged on two opposite sides of the channel region along a direction perpendicular to the top surface of the substrate 10.

Moreover, along the first direction D1 and the second direction D2, a width of the source region is greater than a width of the channel region, and a width of the drain region is greater than the width of the channel region.

Specifically, along the third direction D3, the drain region is located below the channel region, the source region is located above the channel region, and the drain region is electrically connected to the bottom electrode of the capacitor. Along the first direction D1 and the second direction D2, the widths of the source region and the drain region are both greater than the width of the channel region, thereby providing a larger space for forming the word line 15, which not only helps simplify the manufacturing process of the semiconductor structure, but also helps further reduce the size of the semiconductor structure, to adapt to application requirements of different fields.

In some embodiments, the plurality of word lines 15 are arranged at intervals along the first direction D1; and the transistor structure further includes:
a word line isolation layer 19, located between adjacent ones of the word lines 15.

In some embodiments, the transistor structure further includes:
a protective layer 16, located between the word line isolation layer 19 and the active pillar 13 and covering a sidewall of the source region, and along the first direction D1, an edge of the protective layer 16 is flush with an edge of the word line 15.

Specifically, a material of the protective layer 16 may be, but is not limited to, an insulating material such as nitride (e.g., silicon nitride). The protective layer 16 not only can be used to electrically isolate two adjacent source regions, but also can be used as mask layer during forming of the word line 15, thereby reducing the number of masks and further reducing the manufacturing cost of the semiconductor structure.

In some embodiments, the transistor structure further includes source electrodes 20 located on top surfaces of the active pillars 13; and the bit line structure further includes:
a bit line plug 17, where a bottom surface of the bit line plug 17 is in contact with and connected to the source electrode 20, and a top surface of the bit line plug 17 is electrically connected to the bit line 18.

Specifically, the bit line plug 17 has one end electrically connected to the source electrode 20 and another end electrically connected to the bit line 18. The bit line 18 extends along the first direction D1, and the plurality of bit lines 18 are arranged at intervals along the second direction D2. Each of the bit lines 18 is electrically connected, through the bit line plug 17, to the plurality of source electrodes 20 arranged at intervals along the first direction D1. A material of the bit line plug 17 may be the same as a material of the bit line 18, for example, the material is tungsten or molybdenum.

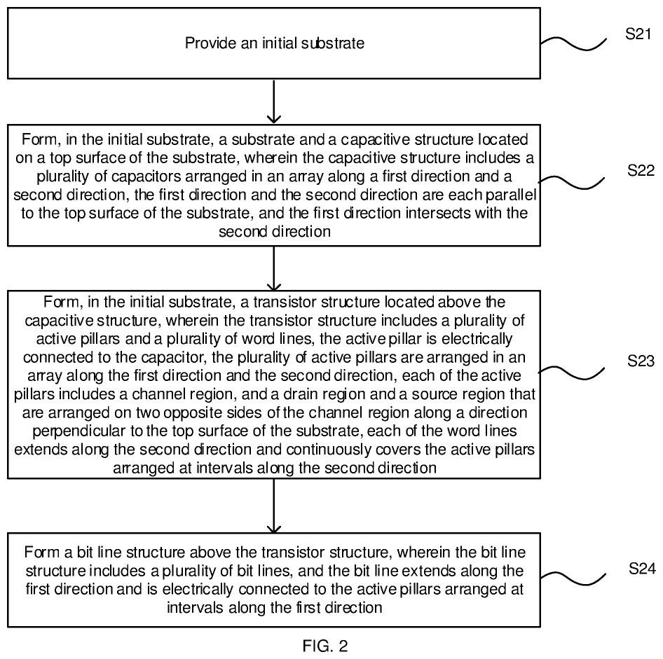

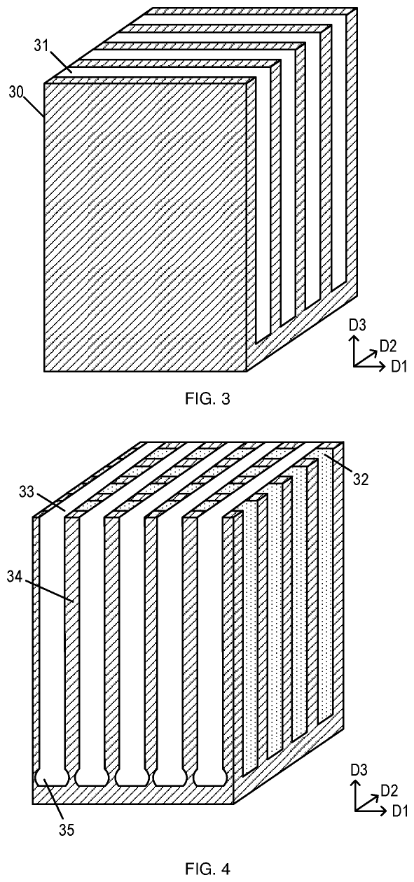

The specific implementation further provides a method of forming a semiconductor structure. FIG. 2 is a flowchart of a method of forming a semiconductor structure according to a specific implementation of the present disclosure. FIG. 3 to FIG. 15 are schematic structural diagrams of main processes for forming a semiconductor structure according to a specific implementation of the present disclosure. For the schematic is diagram of a semiconductor structure formed in the specific implementation, refer to FIG. 1. As shown in FIG. 1 to FIG. 15, the method of forming a semiconductor structure includes the following steps:

Step S21: Provide an initial substrate 30, as shown in FIG. 3.

Specifically, the initial substrate 30 may be, but is not limited to, a silicon substrate. This specific implementation is described by using an example in which the initial substrate 30 is the silicon substrate. In other examples, the initial substrate 30 may be a semiconductor substrate such as a gallium nitride substrate, a gallium arsenide substrate, a gallium carbide substrate, a silicon carbide substrate or a silicon-on-insulator (SOI) substrate.

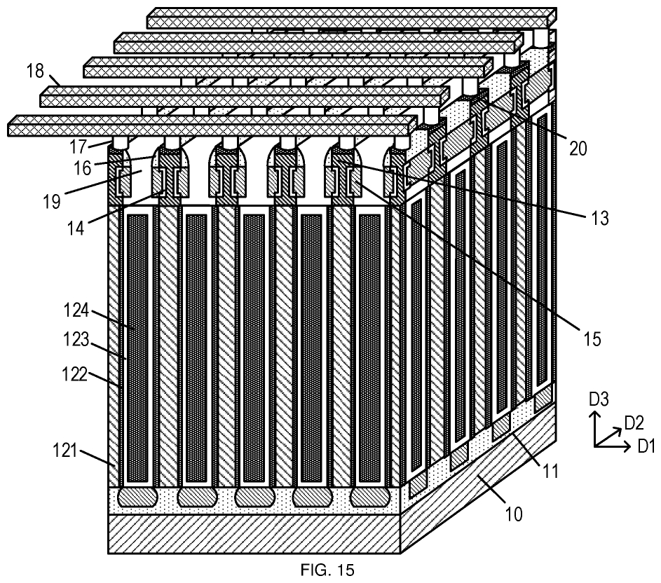

Step S22: Form, in the initial substrate 30, a substrate 10 and a capacitive structure located on a top surface of the substrate 10, where the capacitive structure includes a plurality of capacitors arranged in an array along a first direction D1 and a second direction D2, the first direction D1 and the second direction D2 are each parallel to the top surface of the substrate 10, and the first direction D1 intersects with the second direction D2, as shown in FIG. 10 and FIG. 15.

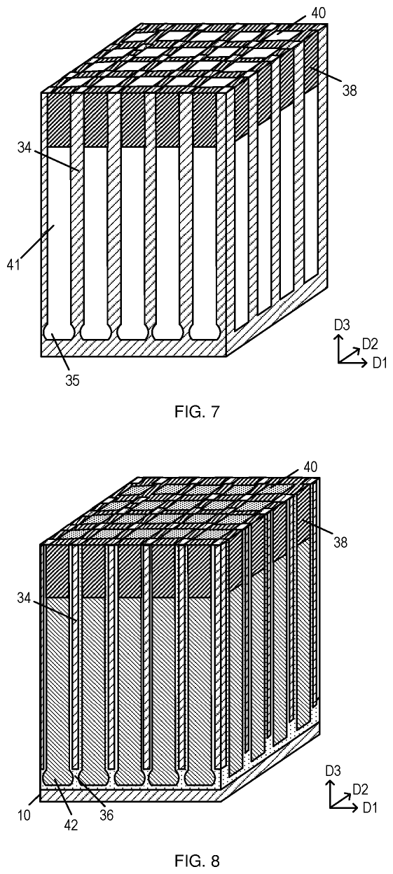

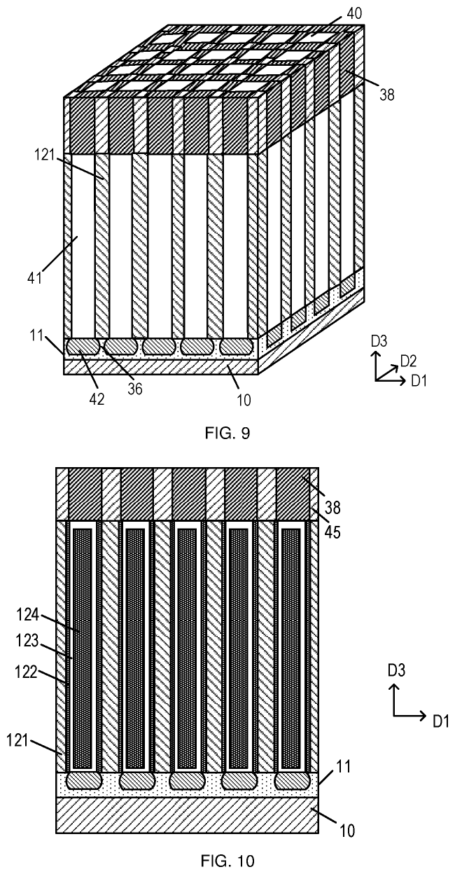

In some embodiments, the step of forming, in the initial substrate 30, a substrate 10 and a capacitive structure located on a top surface of the substrate 10 specifically includes:
etching the initial substrate 30, and forming a plurality of semiconductor pillars 34 arranged in an array along the first direction D1 and the second direction D2, etching holes 41 each located between adjacent ones of the semiconductor pillars 34, and a plurality of recesses 35 in communication with the plurality of etching holes 41 in a one-to-one manner and located below the etching holes 41, as shown in FIG. 7;
forming a substrate isolation layer 11 connecting adjacent ones of the recesses 35 and filling up the recesses 35, and using the initial substrate 30 below the substrate isolation layer 11 as the substrate 10, as shown in FIG. 9; and
forming a capacitor in the etching hole 41, as shown in FIG. 10.

In some embodiments, the step of forming a plurality of semiconductor pillars 34 arranged in an array along the first direction D1 and the second direction D2, etching is holes 41 each located between adjacent ones of the semiconductor pillars 34, and a plurality of recesses 35 in communication with the plurality of etching holes 41 in a one-to-one manner and located below the etching holes 41 specifically includes:
etching the initial substrate 30, and forming a plurality of first etching grooves 31, where each of the first etching grooves 31 extends along the first direction D1, and the plurality of first etching grooves 31 are arranged at intervals along the second direction D2, as shown in FIG. 3;
etching the initial substrate 30 to form a plurality of second etching grooves 33, where each of the second etching grooves 33 extends along the second direction D2, and the plurality of second etching grooves 33 are arranged at intervals along the first direction D1;
etching the initial substrate 30 at the bottom of each of the second etching grooves 33 to form, in the first direction D1, the recess 35 which is wider than the second etching groove 33, as shown in FIG. 4; and
connecting the first etching grooves 31 and the second etching grooves 33 to form the plurality of etching holes 41 and the semiconductor pillars 34 each located between adjacent ones of the etching holes 41.

In some embodiments, the step of forming the recess 35 which is wider than the second etching groove 33 specifically includes:
etching the initial substrate 30 at the bottom of the second etching groove 33 by using a Bosch etching process, to form the recess 35.

Specifically, the initial substrate 30 is etched along the third direction D3 by using a lithography process, to form a plurality of first etching grooves 31 that do not penetrate the initial substrate 30, where each of the first etching grooves 31 extends along the first direction D1, and the plurality of first etching grooves 31 are arranged at intervals along the second direction D2. The first etching groove 31 has a depth of 500 nm to 1200 nm along the third direction D3. Next, a material such as an oxide (such as silicon dioxide) to fill up the first etching groove 31, to form the first medium layer 32, as shown in FIG. 4. The first medium layer 32 is configured to support the initial substrate 30, to prevent the initial substrate 30 from tipping or collapsing during the process of forming the second etching groove 33. After the first medium layer 32 is formed, the initial substrate 30 may be etched again along the third direction D3 by using a lithography process, to form a plurality of second etching grooves 33 not penetrating the initial substrate 30, where each of the second etching grooves 33 extends along the second direction D2, and the plurality of second etching grooves 33 are arranged at intervals along the first direction D1. A depth of the second etching groove 33 along the third direction D3 may be less than that of the first etching groove 31, to facilitate subsequent forming of the recess 35 below the second etching groove 33. After the second etching groove 33 is formed, the initial substrate 30 is at the bottom of the second etching groove 33 is etched by using the Bosch etching process, to form the recess 35 that is in communication with the second etching groove 33 and has an inner diameter greater than that of the second etching groove 33, as shown in FIG. 4. The inner diameter of the recess 35 is greater than the inner diameter of the second etching groove 33. Therefore, in the first direction D1, a width of the semiconductor pillar 34 between adjacent ones of the second etching grooves 33 is greater than a width of the semiconductor pillar 34 between adjacent ones of the recesses 35.

In this specific implementation, the recess 35 is formed by using the Bosch etching process after the second etching groove 33 is formed, so as to simplify a forming process of the semiconductor structure. In other specific implementations, those skilled in the art can also select another etching process as needed to form the second etching groove 33 and the recess 35 connected to the second etching groove 33.

In some embodiments, the step of forming, in the initial substrate 30, a substrate 10 and a capacitive structure located on a top surface of the substrate 10 specifically further includes:
forming a sacrificial layer 37 filling up the etching hole 41 and the recess 35;
etching back a part of the sacrificial layer 37 from the top surface of the initial substrate 30, to expose an upper portion of the semiconductor pillar 34, as shown in FIG. and
forming, on a top surface of the sacrificial layer 37, a support layer 38 covering the exposed semiconductor pillar 34, as shown in FIG. 6.

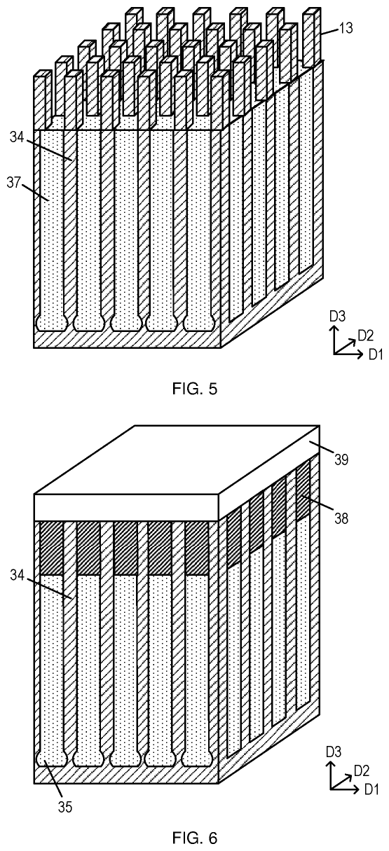

Specifically, after the recess 35 is formed, an oxide (such as silicon dioxide) is deposited in the second etching groove 33 and the recess 35 to form a second medium layer filling up the second etching groove 33 and the recess 35. The first medium layer 32 and the second medium layer jointly form the sacrificial layer 37. Then, a part of the sacrificial layer 37 is etched back to expose the upper portion of the semiconductor pillar 34, as shown in FIG. 5. The exposed semiconductor pillar 34 may have a height of 50 nm to 200 nm along the third direction D3. Next, a support material is deposited on the top surface of the sacrificial layer 37 to form the support layer 38 covering the exposed semiconductor pillar 34. After the support layer 38 is planarized, the first mask layer 39 is formed on the top surface of the support layer 38, as shown in FIG. 6. The support material may be, but is not limited to, a nitride material (such as silicon nitride). A material of the first mask layer 39 may be, but is not limited to, a hard mask material such as polysilicon. On one hand, the support layer 38 protects the upper portion of the semiconductor pillar 34, to prevent the subsequent process of forming the capacitor from damaging the upper portion of the semiconductor pillar 34. On the other hand, the support layer 38 is further configured to support the semiconductor pillar 34, to prevent the semiconductor pillar 34 from tipping after the sacrificial layer 37 is removed subsequently.

In some embodiments, after the forming, on a top surface of the sacrificial layer 37, a support layer 38 covering the exposed semiconductor pillar 34, the method further includes the following steps:
removing the sacrificial layer 37, as shown in FIG. 7;
oxidizing the semiconductor pillar 34 between adjacent ones of the recesses 35, to form a first substrate isolation sub-layer 36; and
filling the recess 35 with an insulation material, to form a second substrate isolation sub-layer 42, where the first substrate isolation sub-layer 36 and the second substrate isolation sub-layer 42 are jointly used as the substrate isolation layer 11, as shown in FIG. 9.

Specifically, the first mask layer 39 is patterned by using a lithography process, to form, in the first mask layer 39, a plurality of first openings that penetrate the first mask layer 39 and expose the support layer 38. The first mask layer 39 is patterned by using a mask in which the first etching grooves 31 and the second etching grooves 33 are formed, such that the positions of the formed plurality of first openings are aligned with the plurality of etching holes respectively. The support layer 38 is etched downward along the first opening, to form, in the support layer 38, the second opening 40 exposing the sacrificial layer 37. After the first mask layer 39 is removed, the sacrificial layer 37 is removed by etching along the second opening 40, to obtain the structure as shown in FIG. 7.

After the sacrificial layer 37 is removed, in-situ oxidation may be performed on the semiconductor pillar 34 below the support layer 38. For example, the semiconductor pillar 34 below the support layer 38 is oxidized by using an in-situ steam generation method. The inner diameter of the recess 35 is greater than the inner diameter of the second etching groove 33. Therefore, in the first direction D1, a width of the semiconductor pillar 34 between adjacent ones of the second etching grooves 33 is greater than a width of the semiconductor pillar 34 between adjacent ones of the recesses 35. Therefore, oxidation parameters (for example, oxidation time and an oxidant dosage) can be controlled to completely oxidize the semiconductor pillar 34 between adjacent ones of the recesses 35 and oxidize the surface of the semiconductor pillar 34 between adjacent ones of the etching holes 41, so as to form the first substrate isolation sub-layer 36 covering the sidewall of the etching hole 41, located between the adjacent ones of the recesses 35, and covering the bottom surface of the recess 35. After that, the second substrate isolation sub-layer 42 is deposited along the second opening 40, to form the structure as shown in FIG. 8. Next, back etching is performed to remove the first substrate isolation sub-layer 36 and the second substrate isolation sub-layer 42 that are located in the etching hole 41, where the remaining first substrate isolation sub-layer 36 and second substrate isolation sub-layer 42 are jointly used as the substrate isolation layer 11, as shown in FIG. 9.

In some embodiments, the etching hole 41 located between the substrate isolation layer 11 and the support layer 38 is used as a capacitor hole, and a material of the initial substrate 30 is silicon; and the step of forming a capacitor in the etching hole 41 specifically includes:
implanting first dopant ions into the semiconductor pillar 34 between adjacent ones of the capacitor holes, to form an initial conductive pillar;
depositing a metal material on the initial conductive pillar, to form a conductive pillar 121 whose material includes a silicide, as shown in FIG. 9; and
sequentially forming a conductive layer 122 covering a sidewall of the conductive pillar 121, a dielectric layer 123 covering a sidewall of the conductive layer 122, and a top electrode 124 covering a surface of the dielectric layer 123, as shown in FIG. 10.

Specifically, after the first substrate isolation sub-layer 36 and the second substrate isolation sub-layer 42 in the etching hole 41 are removed through back etching, the first dopant ions (such as N-type ions) are implanted to the semiconductor pillar 34 between adjacent ones of the capacitor holes by using a plasma implantation or vapor diffusion method, to form an initial conductive pillar, to enhance the conductivity of the initial conductive pillar. Then, a metal material such as nickel is deposited on the surface of the initial conductive pillar through an atomic layer deposition process; next, the conductive pillar 121 made of metal silicide is formed through thermal processing, to further enhance the conductivity of the conductive pillar 121. Then, the conductive layer 122 covering the sidewall of the conductive pillar 121, the dielectric layer 123 covering the sidewall of the conductive layer 122, and the top electrode 124 covering the surface of the dielectric layer 123 are sequentially formed, to form the capacitor including the conductive pillar 121, the conductive layer 122, the dielectric layer 123, and the top electrode 124.

To reduce the etching steps and further simplify the manufacturing process of the semiconductor structure, in some embodiments, the step of forming a conductive layer 122 covering a sidewall of the conductive pillar 121 specifically includes:
directly forming, by using a selective atomic layer deposition process, the conductive layer 122 covering only the sidewall of the conductive pillar 121.

In some embodiments, the dielectric layer 123 is made of any one or more of strontium titanate, aluminum oxide, zirconium oxide, and hafnium oxide, and the conductive layer 122 and the top electrode each are made of any one or more of titanium, ruthenium, ruthenium oxide, and titanium nitride.

Specifically, the dielectric layer 123 may be made of a strontium titanate (STO) material with a high dielectric constant (HK); the conductive layer 122 and the top is electrode 124 may be made of ruthenium or ruthenium oxide, etc., thereby reducing the height of the capacitor along the third direction D3, and reducing the etching depth during etching if the capacitor hole for forming the capacitor, to further reduce the process difficulty. In other examples, the dielectric layer 123 may be made of any one or more of aluminum oxide, zirconium oxide, and hafnium oxide; accordingly, the conductive layer 122 and the top electrode 124 are made of TiN, etc., to reduce the manufacturing cost of the semiconductor layer structure.

Step S23: Form, in the initial substrate 30, a transistor structure located above the capacitive structure, where the transistor structure includes a plurality of active pillars 13 and a plurality of word lines 15, the active pillars 13 are electrically connected to the capacitors, and the word lines 15 extend along the second direction D2 and continuously cover the active pillars 13 arranged at intervals along the second direction D2, as shown in FIG. 14.

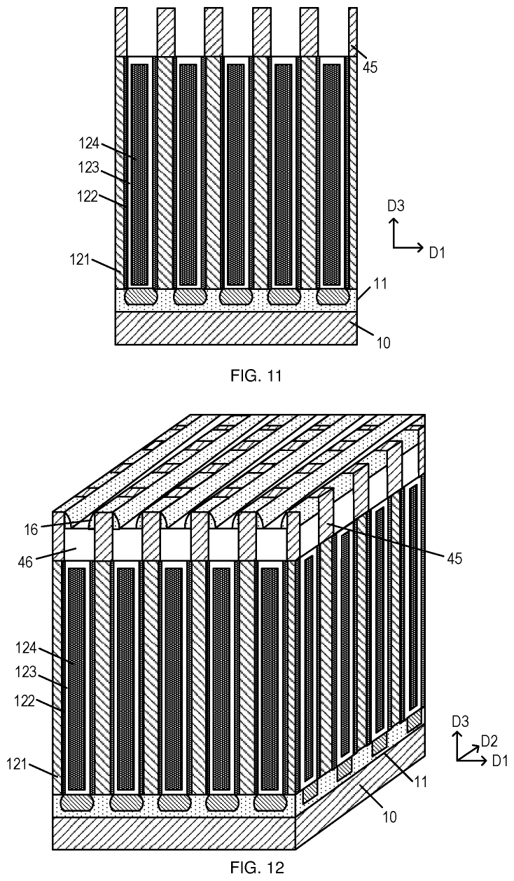

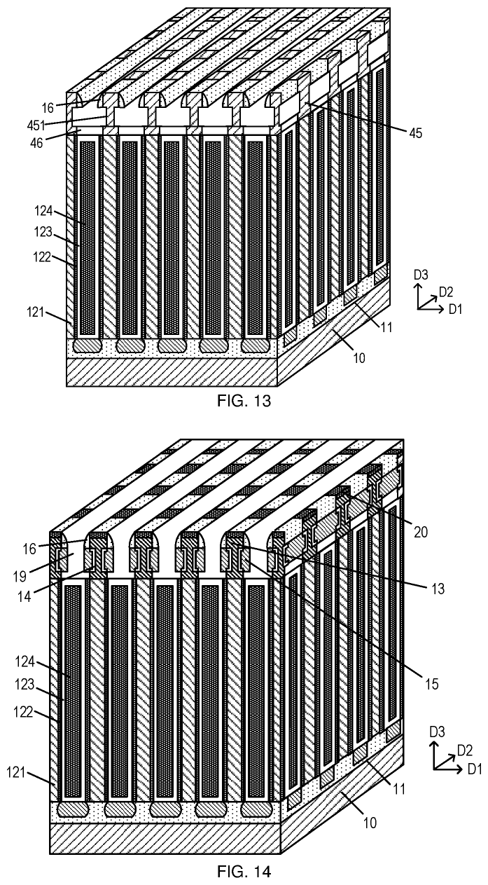

In some embodiments, the step of forming, in the initial substrate 30, a transistor structure located above the capacitive structure specifically includes:
removing the support layer 38 to expose upper portions of the etching holes 41 and the upper portions of the semiconductor pillars 34, using the exposed semiconductor pillars 34 as the active pillars 13, and defining, in each of the active pillars 13, a channel region, a drain region located below the channel region and in contact with the conductive pillar 121, and a source region located above the channel region, as shown in FIG. 11;
reducing widths of the channel region 451 along the first direction D1 and the second direction D2, as shown in FIG. 13; and
forming the word lines 15 extending along the second direction D2 and continuously covering the plurality of channel regions that are arranged at intervals along the second direction D2, as shown in FIG. 14.

In some embodiments, the step of reducing widths of the channel region along the first direction D1 and the second direction D2 specifically includes:
forming a filling layer 46 that fills up the etching hole 41 between the adjacent ones of the active pillars 13, as shown in FIG. 12;
etching back a part of the filling layer 46, to expose the source region;
forming a protective layer 16 covering a sidewall of the source region, as shown in FIG. 12;
etching back a part of the filling layer 46 again to expose the channel region 451, and using the remaining filling layer 46 on a sidewall of the drain region as an initial isolation layer;
performing modification processing on a sidewall of the exposed channel region 451 to form a modified layer; and
removing the modified layer, to reduce the widths of the channel region 451 along the first direction D1 and the second direction D2.

Specifically, after the protective layer 16 is formed, a part of the filling layer 46 is further etched back to form the channel region 451 in the active pillar 13. In the back etching process, to avoid penetration of the filling layer 46, a one-step etching process or a two-step etching process may be used and appropriate etching parameters (for example, a temperature or a pressure) are selected, such that a particular thickness of the first initial isolation layer can be retained. Specifically, the sidewall of the source region in the active pillar 13 is covered by the protective layer 16, and the sidewall of the drain region is covered by the initial isolation layer. Therefore, the modification processing on the channel region 451 does not cause damage to the source region and the drain region. In this specific implementation, the modification processing is performed on the sidewall of the channel region 451, such that there is a relatively high etch selectivity (for example, an etch selectivity greater than 3) between the sidewall of the channel region 451 and the interior of the channel region 451 surrounded by the sidewall of the channel region 451. In this way, the modified sidewall of the channel region 451 can be subsequently removed through selective etching, thereby reducing the width of the channel region 451 and enlarging the gap between adjacent ones of the channel regions 451, to reserve a larger space for subsequent forming of the word lines 15.

Because a thermal oxidation processing operation process is relatively simple, in some embodiments, the modification processing is thermal oxidation processing, and the modified layer is an oxide layer.

After the widths of the channel region 451 along the first direction D1 and the second is direction D2 are reduced, the sidewall of the channel region is oxidized, to form the gate dielectric layer 14. Then, the word line 15 only extending along the second direction D2 is directly formed by using the selective atomic layer deposition process. Next, a second initial isolation layer is deposited between adjacent ones of the active pillars 13, to form the word line isolation layer 19 including the first initial isolation layer and the second initial isolation layer.

In other examples, after a word line material is deposited by using an atomic layer deposition process, the word line material is etched back, to form the word line 15 only extending along the second direction D2.

In some embodiments, after the forming the word lines 15 extending along the second direction D2 and continuously covering the plurality of channel regions that are arranged at intervals along the second direction D2, the method further includes:
implanting second dopant ions to the source region, the channel region, and the drain region, where the second dopant ions and the first dopant ions are of a same ion type.

In some embodiments, after the implanting second dopant ions to the source region, the channel region, and the drain region, the method further includes the following step:
depositing a metal material on a surface of the source region to form a source electrode 20 whose material includes a silicide, as shown in FIG. 14.

Step S24: Form a bit line structure above the transistor structure, where the bit line structure includes a plurality of bit lines 18, and the bit line 18 extends along the first direction D1 and are electrically connected to the active pillars 13 arranged at intervals along the first direction D1, as shown in FIG. 15.

In some embodiments, the step of forming a bit line structure above the transistor structure specifically includes:
forming a plurality of bit line plugs 17 located on top surfaces of the plurality of source electrodes 20 respectively; and
forming the plurality of bit lines 18 above the bit line plugs 17, where the plurality of bit lines 18 are arranged at intervals along the second direction D2, and each of the bit lines 18 extends along the first direction D1 and is in contact with and electrically connected to the plurality of bit line plugs 17 arranged at intervals along the first direction D1.

In the semiconductor structure and the forming method thereof provided by some embodiments of the specific implementation, the transistor structure is arranged above the capacitive structure, and the bit line structure is arranged above the transistor structure, to form a semiconductor structure having a TOC structure. It is unnecessary to form a bit line structure below the transistor structure through a deep hole etching process, thereby reducing the manufacturing difficulty of bit lines, and reducing the manufacturing cost of the semiconductor structure. Moreover, because the bit line structure is located above the transistor structure, the bit line may be manufactured using various materials (such as a metal material), which helps reduce the resistance of the bit line and improve the performance of the semiconductor structure, such that the bit line is more compatible with a subsequent peripheral circuit process.

The above described are merely preferred implementations of the present disclosure. It should be noted that several improvements and modifications may further be made by a person of ordinary skill in the art without departing from the principle of the present disclosure, and such improvements and modifications should also be deemed as falling within the protection scope of the present disclosure.

1. A semiconductor structure, comprising:
a substrate;
a capacitive structure, located on a top surface of the substrate and comprising a plurality of capacitors arranged in an array along a first direction and a second direction, wherein the first direction and the second direction are each parallel to the top surface of the substrate, and the first direction intersects with the second direction;
a transistor structure, located above the capacitive structure and comprising a plurality of active pillars and a plurality of word lines, wherein the active pillar is electrically connected to the capacitor, and the word line extends along the second direction and continuously cover the active pillars arranged at intervals along the second direction; and
a bit line structure, located above the transistor structure and comprising a plurality of bit lines, wherein the bit line extends along the first direction and are electrically connected to the active pillars arranged at intervals along the first direction.

2. The semiconductor structure according to claim 1, further comprising:
a substrate isolation layer, located between the substrate and the capacitive structure.

3. The semiconductor structure according to claim 2, wherein the capacitor comprises:
a bottom electrode, comprising a conductive pillar and a conductive layer covering a surface of the conductive pillar, wherein a top surface of the conductive pillar is in contact with and electrically connected to the active pillar;
a dielectric layer, covering a surface of the conductive layer; and
a top electrode, covering a surface of the dielectric layer.

4. The semiconductor structure according to claim 3, wherein the substrate isolation layer comprises:
a first substrate isolation sub-layer, continuously distributed below the plurality of conductive pillars; and
a second substrate isolation sub-layer, covering a surface of the first substrate isolation sub-layer.

5. The semiconductor structure according to claim 3, wherein the dielectric layer is made of any one or more of strontium titanate, aluminum oxide, zirconium oxide, and hafnium oxide, and the conductive layer and the top electrode each are made of any one or more of titanium, ruthenium, ruthenium oxide, and titanium nitride; and
a material of the conductive pillar is a silicide material comprising first dopant ions.

6. The semiconductor structure according to claim 3, wherein the plurality of word lines are arranged at intervals along the first direction; and the transistor structure further comprises:
a word line isolation layer, located between adjacent ones of the word lines.

7. The semiconductor structure according to claim 6, wherein each of the active pillars comprises a channel region, and a drain region and a source region that are arranged on two opposite sides of the channel region along a direction perpendicular to the top surface of the substrate; and
along the first direction and the second direction, a width of the source region is greater than a width of the channel region, and a width of the drain region is greater than the width of the channel region.

8. The semiconductor structure according to claim 7, wherein the transistor structure further comprises:
a protective layer, located between the word line isolation layer and the active pillar and covering a sidewall of the source region, and along the first direction, an edge of the protective layer is flush with an edge of the word line.

9. The semiconductor structure according to claim 1, wherein the transistor structure further comprises a source electrode located on a top surface of the active pillar; and the bit line structure further comprises:
a bit line plug, wherein a bottom surface of the bit line plug is in contact with and connected to the source electrode, and a top surface of the bit line plug is electrically connected to the bit line.

10. A method of forming a semiconductor structure, comprising:
providing an initial substrate;
forming, in the initial substrate, a substrate and a capacitive structure located on a top surface of the substrate, wherein the capacitive structure comprises a plurality of capacitors arranged in an array along a first direction and a second direction, the first direction and the second direction are each parallel to the top surface of the substrate, and the first direction intersects with the second direction;
forming, in the initial substrate, a transistor structure located above the capacitive structure, wherein the transistor structure comprises a plurality of active pillars and a plurality of word lines, the active pillar is electrically connected to the capacitor, and the word line extends along the second direction and continuously cover the active pillars arranged at intervals along the second direction; and
forming a bit line structure above the transistor structure, wherein the bit line structure comprises a plurality of bit lines, and the bit line extends along the first direction and are electrically connected to the active pillars arranged at intervals along the first direction.

11. The method of forming the semiconductor structure according to claim 10, wherein the forming, in the initial substrate, a substrate and a capacitive structure located on a top surface of the substrate specifically comprises:
etching the initial substrate, and forming a plurality of semiconductor pillars arranged in an array along the first direction and the second direction, etching holes each located between adjacent ones of the semiconductor pillars, and a plurality of recesses in communication with the plurality of etching holes in a one-to-one manner and located below the etching holes;
forming a substrate isolation layer connecting adjacent ones of the recesses and filling up the recesses, and using the remaining initial substrate below the substrate isolation layer as the substrate; and
forming a capacitor in the etching hole.

12. The method of forming the semiconductor structure according to claim 11, wherein the forming a plurality of semiconductor pillars arranged in an array along the first direction and the second direction, etching holes each located between adjacent ones of the semiconductor pillars, and a plurality of recesses in communication with the plurality of etching holes in a one-to-one manner and located below the etching holes specifically comprises:
etching the initial substrate, and forming a plurality of first etching grooves, wherein each of the first etching grooves extends along the first direction, and the plurality of first etching grooves are arranged at intervals along the second direction;
etching the initial substrate, and forming a plurality of second etching grooves, wherein each of the second etching grooves extends along the second direction, and the plurality of second etching grooves are arranged at intervals along the first direction;
etching the initial substrate at a bottom of each of the second etching grooves to form, in the first direction, a width of the recess which is greater than a width of the second etching groove; and
connecting the first etching grooves and the second etching grooves to form the plurality of etching holes and the semiconductor pillars each located between adjacent ones of the etching holes;
wherein the forming a width of the recess is greater than a width of the second etching groove specifically comprises:
etching the initial substrate at the bottom of the second etching groove by using a Bosch etching process, to form the recess.

13. The method of forming the semiconductor structure according to claim 12, wherein the forming, in the initial substrate, a substrate and a capacitive structure located on a top surface of the substrate further specifically comprises:
forming a sacrificial layer filling up the etching hole and the recess;
etching back a part of the sacrificial layer from the top surface of the initial substrate, to expose an upper portion of the semiconductor pillar; and
forming, on a top surface of the sacrificial layer, a support layer covering the exposed semiconductor pillar.

14. The method of forming a semiconductor structure according to claim 13, wherein after the forming, on a top surface of the sacrificial layer, a support layer covering the exposed semiconductor pillar, the method further comprises:
removing the sacrificial layer;
oxidizing the semiconductor pillar between adjacent ones of the recesses, to form a first substrate isolation sub-layer; and
filling the recess with an insulation material, to form a second substrate isolation sub-layer, wherein the first substrate isolation sub-layer and the second substrate isolation sub-layer are jointly used as the substrate isolation layer.

15. The method of forming the semiconductor structure according to claim 14, wherein the etching hole located between the substrate isolation layer and the support layer is used as a capacitor hole, and a material of the initial substrate is silicon; and the forming a capacitor in the etching hole specifically comprises:
implanting first dopant ions into the semiconductor pillar between adjacent ones of the capacitor holes, to form an initial conductive pillar;
depositing a metal material on the initial conductive pillar, to form a conductive pillar whose material comprises a silicide; and
sequentially forming a conductive layer covering a sidewall of the conductive pillar, a dielectric layer covering a sidewall of the conductive layer, and a top electrode covering a surface of the dielectric layer;
wherein the forming a conductive layer covering a sidewall of the conductive pillar specifically comprises:
directly forming, by using a selective atomic layer deposition process, the conductive layer covering only the sidewall of the conductive pillar.

16. The method of forming the semiconductor structure according to claim 15, wherein the dielectric layer is made of any one or more of strontium titanate, aluminum oxide, zirconium oxide, and hafnium oxide, and the conductive layer and the top electrode each are made of any one or more of titanium, ruthenium, ruthenium oxide, and titanium nitride.

17. The method of forming the semiconductor structure according to claim 15, wherein the forming, in the initial substrate, a transistor structure located above the capacitive structure specifically comprises:
removing the support layer to expose an upper portion of the etching hole and the upper portion of the semiconductor pillar, using the exposed semiconductor pillar as the active pillar, and defining, in the active pillar, a channel region, a drain region located below the channel region and in contact with the conductive pillar, and a source region located above the channel region;
reducing a width of the channel region along the first direction and the second direction; and
forming the word line extending along the second direction and continuously covering the plurality of channel regions that are arranged at intervals along the second direction.

18. The method of forming the semiconductor structure according to claim 17, wherein the reducing a width of the channel region along the first direction and the second direction specifically comprises:
forming a filling layer that fills up the etching hole between the adjacent ones of the active pillars;
etching back a part of the filling layer, to expose the source region;
forming a protective layer covering a sidewall of the source region;
etching back a part of the filling layer again to expose the channel region, and using the remaining filling layer on a sidewall of the drain region as an initial isolation layer;
performing modification processing on a sidewall of the exposed channel region to form a modified layer; and
removing the modified layer, to reduce the width of the channel region along the first direction and the second direction;
wherein the modification processing is thermal oxidation processing, and the modified layer is an oxide layer.

19. The method of forming a semiconductor structure according to claim 17, wherein after the forming the word line extending along the second direction and continuously covering the plurality of channel regions that are arranged at intervals along the second direction, the method further comprises:
implanting second dopant ions to the source region, the channel region, and the drain region, wherein the second dopant ions and the first dopant ions are of a same ion type;
wherein after the implanting second dopant ions to the source region, the channel region, and the drain region, the method further comprises:
depositing the metal material on a surface of the source region to form a source electrode whose material comprises a silicide.

20. The method of forming the semiconductor structure according to claim 19, wherein the forming a bit line structure above the transistor structure specifically comprises:
forming a plurality of bit line plugs located on top surfaces of the plurality of source electrodes respectively; and
forming the plurality of bit lines above the bit line plugs, wherein the plurality of bit lines are arranged at intervals along the second direction, and each of the bit lines extends along the first direction and is in contact with and electrically connected to the plurality of bit line plugs arranged at intervals along the first direction.
